(19) United States
(12) Patent Application Publication
(10) Pub. No.: US 2005/0175209 A1
(43) Pub. Date: Aug. 11, 2005

(54) Integrated Speaker Device

(75) Inventor: Arthur Richard Powers Jr., Port Chester, NY (US)

Correspondence Address: LACKENBACH SIEGEL, LLP, LACKENBACH SIEGEL BUILDING, 1 CHASE ROAD, SCARSDALE, NY, 10583, US

(73) Assignee: MADISON FIELDING, INC., Port Chester, NY (US)

(21) Appl. No.: 10/708,100

(22) Filed: Feb. 9, 2004

(51) Int. Cl. H05K 5/00; H04R 9/06; H04R 11/04

(52) U.S. Cl. 381/355; 381/336; 181/153

(57) ABSTRACT

A stage speaker system includes a rear cover portion and a body unit containing a speaker. The rear cover optionally functions as a reverberation chamber and a sound-resistant seal enabling an opening for the increase of wavelength transmission while dampening interfering vibrations. The rear cover includes cooling means optionally being radiating fins. A shield or guide unit optionally joins to the central body unit. A computer controlled stage speaker system includes at least one stage speaker or speaker apparatus operably controlled by a computer control system enabling the at least one stage speaker apparatus to positionably reposition and controllably generate, synthesize, or reproduce a digitally or analog signal, audibly or inaudibly, according to a programable and undatable computer controlled sequence, during a use while remaining camouflaged proximate a plurality of similarly designecd stage lights.

### BACKGROUND OF INVENTION

1. Field of the Invention OLE_LINK1 The present invention relates to a speaker unit. More specifically, the present invention relates to stage speaker device readily adapted for use with stage lighting systems, theatrical use, and in use in combinations with theatrical lighting systems, stage lighting control methods, and computer controlled lighting and sound systems.

2. Description of the Related Art Electronic speakers are widespread in the modern culture, and many conventional and specialty speaker designs have been proposed since the initiation of electronic communication. Common six-sided or rectangular speaker designs are frequently used with stereo units and sound production of all kinds. Common circular speaker designs are used in conjunction with non-circular and non-rectangular shapes for convenience. Examples of circular speaker design and use are frequently seen in automotive door panels, front and rear dash board panels, rear door hatch panels, drop ceilings in offices, and in public transportation vehicles.

In certain uses, conventional speakers include an attachment system for securing a speaker to a wall or a ceiling to facilitate use in generating a stereophonic effect for a listener.

In alternative conventional uses, speakers are camouflaged visually from a listener, to provide the listener with the illusion of listening to a live production or to lull a listener into ignoring the physical presence of a speaker and concentrate on an entertainment production or other occurrence. Conventional speaker camouflage systems include the use of camouflage paint or concealment within a non-speaker-looking item such as a rock, post, sign-board, display, or fabric wall. Other simpler conventional camouflage systems involve simply positioning the speaker behind a light blocking object like a curtain, a piece of furniture, or an architectural item.

In conventional theatrical productions, speakers are used for two main purposes. The first is to provide an entertainer with an audible feedback of their vocal performance. With the use of an audible feedback loop, an entertainer can increase, decrease, or change the tonal quality of their voice to match the needs of the performance. Common feedback-speakers are positioned or secured on a stage edge, directly between the audience and the entertainer, are generally geometric in shape having broad flat angular surfaces, and are directly linked with an entertainer”s microphone. In use, as the entertainer vocalizes, the entertainer”s microphone picks up the signal and plays it back through the feedback speaker direct to the individual, occasionally with amplifications or signal manipulation (removal of max/min amplitudes). This type of feedback system is present in all types of entertainment productions from opera to rap.

The second purpose of conventional theatric speakers is to provide an electronically mixed or recorded sound to the audience. This type of use is conventionally done with large rectangular speakers suspended independently or in groups from the ceiling on flexible chains (to minimize vibration), positioned adjacent the stage (stacked on either side), or suspended on the walls of the entertainment facility. In use, digital or analog signals are feed through the speakers to the audience using either wired or wireless communication links. Since, these types of conventional speakers are visually available to the audience members, the speaker units are often painted black, positioned behind the audience, or otherwise hidden from immediate view by a curtain or set piece in an effort to lull the audience into suspending their inherent impression of large adjacent sound source and focus on the entertainment production, thereby mentally integrating the visual and sound impressions provided.

Since conventional speaker systems are commonly fixed (noted above) to eliminate distracting vibration and reverberation, where a sound producer wishes an audience to perceive a movement with a sound (i.e. a rushing car), the sound producer employs a stereophonic effect by splitting the sound signal into two or more sound signals and playing these signals through separate conventional speakers. Since conventional speakers are commonly positioned at opposite sides of a stage, and since most audience members are biaural, this effect provides the illusion of movement to an audience. A widely known audio method employing a sophistication of this technique is the Bose® method created by the well-known Bose® Corporation.

In theatrical productions, extensive lighting and light generating equipment is often positioned all around the theatrical stage, on the walls, the ceiling, and the floor. Conventionally, lighting equipment is rigidly positioned on stands, polls, or grids, suspended above, or in front of, the stage. With these conventional light-positioning modalities, the entertainers are illuminated sufficiently for audience view in a controllable manner since the lights are fixed to a rigid frame.

Unlike with speaker systems, the main concern with light generating equipment is not visual camouflage, but heat dissipation in an effort to maintain electrical efficiency and equipment life. Given the length of common entertainment events, often several hours, unvented/cooled lighting equipment can reach very high temperatures and will fail or be electrically damaged preventing easy repair and reuse. Since convection and conduction are the major forms of heat dissipation in theatrical lighting ready concealment is difficult and is substantially counterproductive. Consequently, conventional stage lights are often painted black, provided with heat dissipating fins, and suspended in midair in a framework in easy view of the audience.

Where theatrical productions are produced out-of-doors, theatrical or stage lighting is often placed in weather resistant housings and theatrical speaker systems are positioned on stage under a roof or other structure. In this manner, an audience still receives basic audio input from the speakers and can view the illuminated entertainers.

Recently, conventional systems for theatrical stage lighting and lighting control have been created that enable a central computer controller to visually control a plurality of stage lights (up to 100 or more lights) of various kinds (LED, incandescent, fluorescent, metal vapor, etc.). The controlling computer systems enable a system operator to control a light”s color selection and intensity, and in some cases, where automated positioning systems are provided, the position (pan/tilt) of a light according to a synchronized control program. Many of these types of conventional stage lighting systems are complex and provide complex computer control and automatic lighting control systems.

Examples of these types of conventional computer controlled stage lighting systems are shown in U.S. Reg. No. 5,406,176 (Sugden) and U.S. Reg. No. 4,962,687 (Belliveau et al.), the contents of which are incorporated entirely herein by reference in explanation of the systems described.

Unfortunately, with the known technology, the theatrical producer is forced to choose between the public positioning of theatrical lighting and the concealment benefits of known stage speaker systems when designing a production set.

### SUMMARY OF INVENTION

OLE_LINK2 Objects and Summary of the Invention

An object of the present invention is to provide a stage speaker device and a stage speaker system remediating the detriments and concerns noted above.

Another object of the present invention is to provide a stage speaker device that can be deceptively positioned and camouflaged from an audience while providing at least one of a selected sound feed-back to a user and a selected sound projection to at least one audience member.

Another object of the present invention is to provide a stage speaker device readily adapted to conventional specialty stage lighting control computer systems.

The present invention relates to a stage speaker system includes a cylindraceous and coaxially aligned rear cover, a central body unit, and a shield or guide unit. The rigid rear cover is sealed to the central body unit providing a waterproof reverberation chamber while dampening interfering vibrations. The rigid rear cover includes cooling means and the central body unit includes a coaxial speaker. A clamping means removable joins the rear cover and central body unit. The shield or guide unit rigidly joins to a front face of the central body unit. A computer controlled stage speaker system includes at least one stage speaker or speaker apparatus operably controlled by a computer control system enabling the at least one stage speaker apparatus to position-ably reposition and controllably generate, synthesize, or reproduce a digitally or analog signal, audibly or inaudibly, according to a programmable and undatable computer controlled sequence during a use while remaining camouflaged proximate a plurality of similarly shaped stage lights.

According to an embodiment of the present invention there is provided a cylindraceous stage speaker system, comprising: a cylindrical body unit having a central axis, the body unit including on an inner diameter a coaxially positioned speaker means having at least a front speaker face and a rear speaker face, the front speaker face positioned at a first side of the body unit opposite an open second side of the body unit, the open second side of the body unit being a first cylindrical opening surrounding the rear speaker face, a cylindraceous rear cover unit having a rigid metallic housing, the rear cover continuously bounding a respective space defined therein in which a medium of electro-mechanical energy absorption is disposed, the rear cover being coaxial to and defining a single second cylindrical opening, the second cylindrical opening coaxial to the first cylindrical opening, clamping means for removably clamping the first cylindrical opening to the second cylindrical opening and for forming at least one of a water-tight and a sound-tight seal between the speaker unit and the rear cover, a cylindraceous shielding unit bounding a third cylindrical opening and a fourth cylindrical opening, the third and fourth cylindrical openings being coaxial to each the first and second cylindrical opening, the third cylindrical opening being removably joined to the first side of the body unit forming at least one of a water-resistant and a sound-resistant joining there between, the shielding unit coaxial to each of the central axis and the body unit, the rear cover, and the speaker means, a total length of the cylindraceous stage speaker system being defined along the central axis, a maximum diameter of the stage speaker being a maximum diameter of the rear cover unit, and a ratio x of the total length to the maximum diameter is defined as substantially about 1.0<<×<<3.5, whereby the stage speaker system is shaped for easy positioning and repositioning during a use by a user.

According to another embodiment of the present invention there is provided a cylindraceous stage speaker system, further comprising: a means for controllably positioning the speaker system relative to at least one external fixture plane, the means for controllably positioning including at least two opposing bosses on the body unit defining a line perpendicular to the central axis, a first set of compression elements threadably engageable with respective the bosses, at least one yoke member, and ones of the set of compression member adjustably connecting respective ends of the yoke member to the opposing bosses, whereby the means for controllably positioning allows a user to repositionably position the speaker system relative to the at external fixture plane.

According to another embodiment of the present invention there is provided a cylindraceous stage speaker system, further comprising: means for securing the rear cover to the main body unit, the means for securing in the means for removably clamping, and the means for securing including at least one of a braided metal cable release-ably joining the rear cover to the main body unit, whereby when the means for removable clamping releases the main body unit the means for securing prevents unintended separation of the rear cover.

According to another embodiment of the present invention there is provided a cylindraceous stage speaker system, further comprising: at least one cover screening member, and means for removably securing the one cover screening member to the fourth cylindrical opening of the shielding unit, whereby the at least one cover screening member substantially covers the fourth cylindrical opening during the use and controls at least one of a visible wavelength entry and reflection, a foreign object entry into the shielding unit, and an energy wavelength exit from the shielding unit.

According to another embodiment of the present invention there is provided a cylindraceous stage speaker system, wherein: the at least one screening member includes at least one of debris grill, an aperture control means for controlling an aperture of the fourth cylindrical opening, a sound transmitting camouflage covering means for preventing an external viewer from viewing the speaker means, and a waterproof-sound-transmitting means for preventing entry of an external moisture to the fourth cylindrical opening during an outdoor use.

According to another embodiment of the present invention there is provided a cylindraceous stage speaker system, further comprising: at least one cover screening member, and means for removably securing the one cover screening member to the fourth cylindrical opening of the shielding unit, whereby the at least one cover screening member substantially covers the fourth cylindrical opening during the use and controls at least one of a visible wavelength entry and reflection, a foreign object entry into the shielding unit, and an energy wavelength exit from the shielding unit.

According to another embodiment of the present invention there is provided a cylindraceous stage speaker system, wherein: the at least one screening member includes at least one of debris grill, an aperture control means for controlling an aperture of the fourth cylindrical opening, a sound transmitting camouflage covering means for preventing an external viewer from viewing the speaker means, and a waterproof-sound-transmitting means for preventing entry of an external moisture to the fourth cylindrical opening during an outdoor use.

According to another embodiment of the present invention there is provided a cylindraceous stage speaker system, further comprising: waterproof means in the rear cover opposite the first cylindrical opening for guiding a wired audio connection from a rear face of the rear cover to the speaker means.

According to another embodiment of the present invention, there is provided a cylindraceous speaker system, further comprising: a plurality of rigid heat-radiating fins, the plurality of fins arrayed about an outer diameter of the rear cover opposite the speaker means, and each the fin radiating a thermal energy of the speaker system to a surrounding atmospheric system, whereby the speaker system prevents an undesirable buildup of thermal energy during the use.

According to another embodiment of the present invention, there is provided a cylindraceous stage speaker system, comprising: a cylindrical body unit having a central axis, the body unit including a coaxially positioned speaker having at least a front speaker face and a rear speaker face, the front speaker face positioned at a first side of the body unit opposite an open second side, a cylindraceous rear cover unit coaxial to the central axis, defining a single circular opening, and continuously bounding a respective enclosed space defined therein in which a medium of electro-mechanical energy absorption is disposed, clamping means for removably clamping the body unit to the rear cover unit and for forming at least one of a water-tight and a sound-tight seal, a cylindraceous shielding unit coaxial to the central axis, a total length of the cylindraceous stage speaker system being defined along the central axis and a maximum diameter of the stage speaker being a maximum diameter of the rear cover unit, and a ratio x of the total length to the maximum diameter is defined as substantially about 1.0<<×<<3.5, whereby the stage speaker system is shaped for easy positioning and repositioning during a use by a user.

According to another embodiment of the present invention there is provided a cylindraceous stage speaker system, further comprising: a means for controllably positioning the speaker system relative to at least one external fixture plane, the means for controllably positioning including at least two opposing bosses on the body unit defining a line perpendicular to the central axis, a first set of compression elements threadably engageable with respective the bosses, at least one yoke member, and ones of the set of compression member adjustably connecting respective ends of the yoke member to the opposing bosses, whereby the means for controllably positioning allows a user to repositionably position the speaker system relative to the at external fixture plane.

According to another embodiment of the present invention there is provided a cylindraceous stage speaker system, further comprising: means for securing the rear cover to the main body unit, the means for securing in the means for removably clamping, and the means for securing including at least one of a braided metal cable release-ably joining the rear cover to the main body unit, whereby when the means for removable clamping releases the main body unit the means for securing prevents unintended separation of the rear cover.

According to another embodiment of the present invention there is provided a cylindraceous stage speaker system, further comprising: at least one cover screening member, and means for removably securing the one cover screening member to the fourth cylindrical opening of the shielding unit, whereby the at least one cover screening member substantially covers the fourth cylindrical opening during the use and controls at least one of a visible wavelength entry and reflection, a foreign object entry into the shielding unit, and an energy wavelength exit from the shielding unit.

According to another embodiment of the present invention there is provided a cylindraceous stage speaker system, wherein: the at least one screening member includes at least one of debris grill, an aperture control means for controlling an aperture of the fourth cylindrical opening, a sound transmitting camouflage covering means for preventing an external viewer from viewing the speaker means, and a waterproof-sound-transmitting means for preventing entry of an external moisture to the fourth cylindrical opening during an outdoor use.

According to another embodiment of the present invention there is provided a cylindraceous stage speaker system, further comprising: at least one cover screening member, and means for removably securing the one cover screening member to the fourth cylindrical opening of the shielding unit, whereby the at least one cover screening member substantially covers the fourth cylindrical opening during the use and controls at least one of a visible wavelength entry and reflection, a foreign object entry into the shielding unit, and an energy wavelength exit from the shielding unit.

According to another embodiment of the present invention there is provided a cylindraceous stage speaker system, wherein: the at least one screening member includes at least one of debris grill, an aperture control means for controlling an aperture of the fourth cylindrical opening, a sound-transmitting or sound-transparent camouflage covering means for preventing an external viewer from viewing the speaker means, and a waterproof-sound-transmitting means for preventing entry of an external moisture to the fourth cylindrical opening during an outdoor use.

According to another embodiment of the present invention there is provided a cylindraceous stage speaker system, further comprising: waterproof means in the rear cover opposite the first cylindrical opening for guiding a wired audio connection from a rear face of the rear cover to the speaker means.

According to another embodiment of the present invention there is provided a cylindraceous stage speaker system, further comprising: a plurality of rigid heat-radiating fins, the plurality of fins arrayed about an outer diameter of the rear cover opposite the speaker means, and each the fin radiating a thermal energy of the speaker system to a surrounding atmospheric system, whereby the speaker system prevents an undesirable buildup of thermal energy during the use.

According to another embodiment of the present invention, there is provided a computer controlled stage speaker system, comprising: at least one speaker system, at least one multi-parameter lighting unit, computer control means for computerized controlling of the at least one speaker system and the multi-parameter lighting unit, and the computer control means enabling a communication means for directing the at least one stage speaker system to position-ably reposition based upon a series of stored movement commands and initiate at least one of a sound generation, a sound synthesis, and a sound reproduction of at least one of a digitally and an analog signal, according to a programable and undatable computer controlled sequence stored in the computer control means during a use.

According to another embodiment of the present invention, there is provided a computer controlled stage speaker system, wherein: the at least one speaker system comprises: a cylindrical body unit having a central axis, the body unit including a coaxially positioned speaker having at least a front speaker face and a rear speaker face, the front speaker face positioned at a first side of the body unit opposite an open second side, a cylindraceous rear cover unit coaxial to the central axis, defining a single circular opening, and continuously bounding a respective enclosed space defined therein in which a medium of electro-mechanical energy absorption is disposed, clamping means for removably clamping the body unit to the rear cover unit and for forming at least one of a water-tight and a sound-tight seal, a cylindraceous shielding unit coaxial to the central axis, a total length of the cylindraceous stage speaker system being defined along the central axis and a maximum diameter of the stage speaker being a maximum diameter of the rear cover unit, and a ratio x of the total length to the maximum diameter is defined as substantially about 1.0<<×<<3.5, whereby the stage speaker system is shaped for easy positioning and repositioning during a use by a user.

According to another embodiment of the present invention, there is provided a computer controlled stage speaker system, wherein: the programmable and undatable computer controlled sequence includes data applicable to at least one of a sound, a position, and an volume parameter set stored in a memory of the computer control system.

According to another embodiment of the present invention, there is provided a computer controlled stage speaker system, comprising: wherein: the communication means includes at least one of a wired and a wireless communication network communicating between the computer control system and the at least one stage speaker system and the lighting unit.

According to another embodiment of the present invention, there is provided a computer controlled stage speaker system, wherein: the at least one communication network communicates at least one of a digital and an analog signal to the at least one speaker system including at least one of an audible and an inaudible signal.

According to another embodiment of the present invention, there is provided a method of mounting at least one stage speaker system, comprising the steps of: selecting at least one cylindraceous stage speaker system camouflaged to mimic a substantially plurality of preselected stage lights positionably fixed on a stage lighting assembly, positionably fixing the at least one stage speaker system on the stage lighting assembly proximate the plurality of stage lights, operably connecting the stage speaker system to a computer control system for controlling a positioning and at least one of an audible and inaudible operation of the speaker system while simultaneously controlling an operation of the plurality of stage lights, whereby the method permits synchronized control of both the plurality of stage lights and the stage speaker system during a performance while permitting a generation of sound to an audience in a visually camouflaged manner.

According to another embodiment of the present invention, there is provided a cylindraceous stage speaker system, comprising: a cylindrical body unit having a central axis, the body unit including a coaxially positioned speaker having at least a front speaker face and a rear speaker face, the front speaker face positioned at a first side of the body unit opposite an open second side, a cylindraceous rear cover unit coaxial to the central axis, defining a single circular opening, and continuously bounding a respective enclosed space defined therein in which a medium of electro-mechanical energy absorption is disposed, clamping means for removably clamping the body unit to the rear cover unit and for forming at least one of a water-tight and a sound-tight seal therewith, a cylindraceous shielding unit coaxial to the central axis on the first side of the body unit, and means for controllably positioning the speaker system relative to at least one external fixture plane.

According to another embodiment of the present invention, there is a cylindraceous stage speaker system, comprising: a cylindrical body unit having a central axis, the body unit including on an inner diameter a coaxially positioned speaker means having at least a front speaker face and a rear speaker face, the front speaker face positioned at a first side of the body unit opposite an open second side of the body unit, the open second side of the body unit being a first cylindrical opening surrounding the rear speaker face, a cylindraceous rear cover unit having a rigid metallic housing, the rear cover continuously bounding a respective space defined therein in which a medium of electro-mechanical energy absorption is disposed, the rear cover being coaxial to and defining a single second cylindrical opening, the second cylindrical opening coaxial to the first cylindrical opening, clamping means for removably clamping the first cylindrical opening to the second cylindrical opening and for forming at least one of a water-tight and a sound-tight seal between the speaker unit and the rear cover, a cylindraceous shielding unit bounding a third cylindrical opening and a fourth cylindrical opening, the third and fourth cylindrical openings being coaxial to each the first and second cylindrical opening, the third cylindrical opening being removably joined to the first side of the body unit forming at least one of a water-resistant and a sound-resistant joining there between, the shielding unit coaxial to each of the central axis and the body unit, the rear cover, and the speaker means.

According to another embodiment of the present invention, there is provided a combination of a cylindraceous stage speaker unit and a multi-parameter stage lighting unit, the combination comprising: at least a first cylindraceous multi-parameter stage lighting unit, at least a first cylindraceous stage speaker unit, the stage lighting unit including at least a first cylindraceous housing having at least a first open end for the projection of an illumination wavelength toward a first selected target, first means for adjustably fixing the first cylindraceous housing to an external lighting unit support structure and enabling an adjustment of the first open end relative to the first selected target during a use, the stage speaker system including at least a second cylindraceous housing substantially similar to the at least first cylindraceous housing and having at least a second open end opposite a third closed end, the second open end enabling the projection of an audible wavelength toward a second selected target, second means for adjustably fixing the second cylindraceous housing to the external light unit support structure and enabling an adjustment of the second open end relative to the second selected target during the use, and the second means for adjustably fixing be substantially similar to the first means for adjustably fixing, whereby the stage lighting unit and the stage speaker system are substantially similar in outward appearance to a viewer.

According to another embodiment of the present invention, there is a combination, further comprising: a second end covering device covering the second open end of the stage speaker system and substantially preventing at least one of an entry and an emission of visible wavelengths of light there-through while remaining substantially transparent to the transmission of audible wavelengths, and the third end of the stage speaker unit being both optically opaque and audibly opaque.

According to another embodiment of the present invention, there is a combination, wherein: the second end covering is at least one of a grill unit and an optically reflective member.

According to another embodiment of the present invention, there is a combination, wherein: the grill unit includes a plurality of openings sufficiently sized to block the entry, reflection, and re-emittance of visible wavelengths of light from an interior of the second cylindraceous housing during the use, whereby an audience is not able to view an interior of the stage speaker unit with reflected light.

The above, and other objects, features and advantages of the present invention will become apparent from the following description read in conduction with the accompanying drawings, in which like reference numerals designate the same elements.

OLE_LINK2

### BRIEF DESCRIPTION OF DRAWINGS

FIG. 1 is a perspective view of one embodiment of the stage speaker device according to the present invention.

FIG. 1A is a descriptive view of the audible tone direction benefit provided by one embodiment of the present invention in a particular circumstance.

FIG. 2 is a partial front view of the embodiment shown in FIG. 1.

FIG. 3 is a close-up partial view of one embodiment of the stage speaker device according to the embodiment shown in FIG. 1.

FIG. 4 is a perspective view of another embodiment of the present invention.

### DETAILED DESCRIPTION

Since common theatrical audience members rapidly adapt to and are readily trained to visually ignore the necessarily ever-present theatrical lights grouped around a stage, the present invention takes advantage of this easily trained human illusionary effect by creating a stage speaker system specifically adapted for camouflage among the theatrical stage lights.

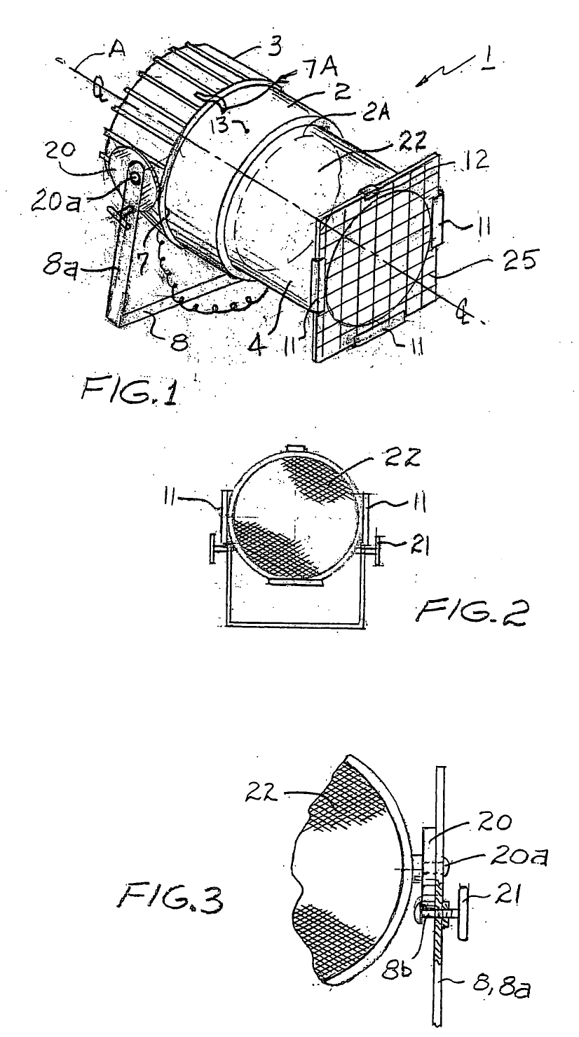

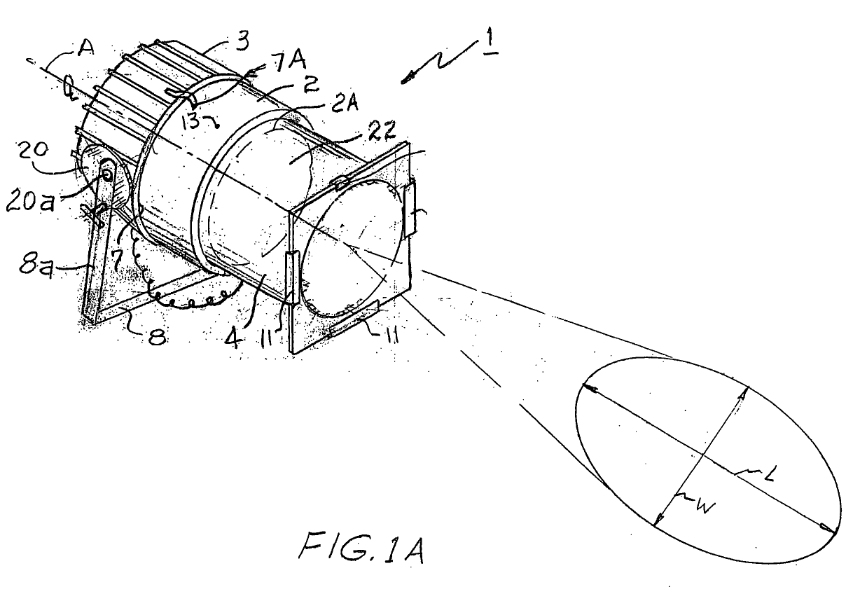

Referring now to FIGS. 1, 1A, and 2, in one embodiment of the present invention, a stage speaker system or device 1 includes a rear cover 3, a body unit 2 (alternatively speaker body unit 2), and a shield or guide unit 4. Rear cover 3, body unit 2, and shield or guide unit 4 are coaxial to a central axis A extending there through.

Speaker body unit 2 is a cylindraceous rigid member (commonly metallic) coaxially supporting a conventional tone generating circular speaker 2A with a front screening member 22 at a first side (both shown in shadow). A second side of body unit 2 extends behind speaker 2A defining a first generally circular opening. A bottom rim extends around the second side of body unit 2 to enable a clamping attachment to rear cover 3, as will be explained.

Rear cover 3 is a rigid member (in the present embodiment being, but not required to be, a cylindraceous rigid member), generally bounding an inner volume and defining an opening coaxial to the central axis. In the present embodiment, a plurality of cooling members or fins 3A (also called heat radiating elements or heat radiators) is arrayed about an outer perimeter of rear cover 3.

In an alternative embodiment, it is envisioned that cooling members 3A may alternatively be understood as a single or multiple heat sink units and even a simple heat radiation coating (including dark color paint). It should be understood, that cooling members 3A, of different types, may be used with or replace all or a plurality of cooling fins 3A shown depending upon a user”s desire to match the outward appearance of an existing speaker array or system. Those skilled in the art of design will further understand that the heat radiating elements (coating, cooling fins, heat sinks etc.) are selectable by a manufacturer or end user to match an existing or a preferred outward user-defined appearance and hence blend in with, compliment, or balance a speaker arrangement and/or lighting arrangement. It should be further understand that it is the outward audience-appearance (as well as the speaker function) of the combined unit that aids a user in blending the speaker into a pre-existing array of lighting units, namely, the speaker unit and any necessary electronic controls are internally mounted (not easily visible) with the “lighting-body” unit, while additionally providing for the benefits mentioned elsewhere (acoustic remediation, easy user adaptability and control, easy computer and motion control, etc.).

In an alternative embodiment, where speaker unit 2A is self powered and may include a permanent or replaceable battery pack (not shown) or other electronic circuitry (for example, positioning drive motors) requiring or benefiting from actual thermal radiation to maintain an optimal temperature, then cooling members 3A may operate to provide a practical cooling effect to the particular circuitry. As noted, cooling members 3A are shown as cooling fins, but should be understood by those skilled in the art to include well known cooling members including radiating patent, heat sinks, cooling loops, electronic coolers etc.

A watertight and/or a sound tight seal 7 is positioned about the circular opening in rear cover 3. Seal 7 enables the positioning of the unit in a weather-vulnerable position and minimizes the risk of sound radiation in an undesirable direction.

A plurality of compression clamps 7a is arrayed about the outer circumference of rear cover 3. During an assembly with body unit 2, clamps 7a on rear cover extend to engage the bottom rim of body unit 2 and clamp body unit 2 to rear cover 3, forming a water-tight and/or sound-tight junction with seal 7. One or more edge gaskets may be used to increase sealing capacity of seal 7, but are not necessary where substantial water/sound blocking surface contact exists. Alternative types of joining methods, including threaded junctions, are also envisioned.

Prior to sealing, as needed, audio wire leads or other electronic circuitry (not shown) for speaker 2A may be fed through a waterproof opening (not shown) on a rear surface of rear cover 3 opposite water tight seal 7, and attached to speaker 2A. In alternative embodiments, a wireless audio relay signal system and power supply system (similar to those used in conventional wireless speaker systems and noted briefly above) may be used to eliminate any need for audio wire and/or power wire leads that would limit unit movement.

While the embodiment shown includes a separate rear cover 3, it is envisioned that rear cover 3 may alternatively be formed integrally with body unit 2 depending upon a manufacturer”s design preference. In this type of integral-formation, no seals or clamps would be necessary. A further embodiment may include a opening or hole in rear cover 3 (not shown) intentionally open to atmospheric pressure. Defined openings of this type are commonly used to transmit long wavelength or base-note sounds in a manner similar to rectangular base-speaker unit. Consequently, by either removing rear cover 3 completely, or by opening a section of rear cover 3, the stage speaker 1 may transmit a broader range of audio and sub-audio wavelengths.

Alone or when joined with body unit 2, rear cover 3 bounds a respective defined space enclosing a medium of electro-mechanical energy absorption such as air, a selected gas, a selected gas and foam combination, sound baffles, or a combination of all of the above as desired by a manufacturer.

In use, as speaker 2A operates, wavelengths of electro-mechanical energy are generated coaxially both toward rear cover 3 and shield or guide unit 4. As will be described, shield or guide unit 4, of a selected length, generally functions to emit the electro-mechanical wavelengths in a controlled manner and rear cover 3 functions generally restrain the wavelengths and to absorb or dampen any resulting vibration or reverberation from reaching a listener. In this manner, stage speaker device 1 may be used as a sound directional device positioned as desired by a user. Alternatively, rear cover 3 may be open to the atmospheric air via a single large opening or a plurality of holes and thereby allow a sound uniformity as desired by an end user. An open access to rear cover 3 also provides for the release of any atmospheric moisture that may accumulate. Of course, a closed and sealed cover would be beneficial in exterior water-exposed applications. It is noted that the rear cover unit need not provide a complete cover and need not be continuous and may be easily adapted to a user”s needs. It is also noted that rear cover unit 3 may be formed integrally with the main body unit and, where needed, with a guide unit embodiment. In this manner, the present invention enables an inexpensive construction where desired by an end user or manufacturer.

In alternative preferred embodiments, the defined space between body unit and rear cover 3 may be filled with simply atmospheric air during an assembly or maintenance. In other preferred embodiments (as noted), the defined space may be filled with a less dense, more readily compressed gas (for example nitrogen or argon) via a pressure purge/fill assembly (not shown), or a closed or open semi-rigid foam bounding gas bubbles containing a selected gas and able to absorb and limit maximum vibrations.

Shield or guide unit 4 is a cylindraceous rigid body defining a third opening end adjacent speaker 2A and a fourth opening end opposite speaker 2A, as shown. The third opening end is coaxial with and securely joined to body unit 2 at its first side. Shield or guide unit 4 may be alternatively referred to by those skilled in the art of lighting design as a snoot or snout and is conventionally used as described below. It is also envisioned that the present embodiment may be operated effectively without the inclusion of a shield or guide unit 4, particularly where an end user does not desire the complete benefits of the unit. In this circumstance, guide unit 4 may be removed after sale or not originally installed.

In one of the preferred embodiments, a flange (shown but not numbered) extends from the third opening end of guide unit 4 and enables a plurality of screws or bolts (shown) to threadably join guide unit 4 to body unit 2, providing a sound-tight (and optionally for external use a second water-tight) seal there-between. In this manner, guide unit 4 is able to receive and guide sound generated from speaker 2A along its bounded length and out the fourth opening towards a desired target. While guide unit 4 is show with a length at least as long as a length of body unit 2, guide unit 4 may be any suitable length selected by a manufacturer, sound engineer, or end user. Other means may be used to join guide unit 4 to body unit 2, including a magnetic seal, clamping means, threaded connections, adhesives, or other joining methods common in the theatrical arts, without passing beyond the spirit an scope of the present invention.

As can be seen from FIG. 1A, the tonal directability provided by the present invention, having a predictable and directable projection width(w) and length(l), in combination with it”s camouflage ability to hide in plain sight among a plurality of conventional stage lighting units, allows an operator of the present invention the benefit of using the device 1 to surgically project sound as needed.

For example, to remediate poor acoustic design for a particular audience section or performer, or to provide a selectable and even movable zone of audible feed-back for a performer (as will be described), thereby allowing a performer to optionally step into and out of a defined audible feed-back zone or to be followed during performance movement by a movable audible feed-back.

In the embodiment shown, a plurality of guide edges 11 and a pivot clamp 12 are arrayed about the fourth opening of guide unit 4. Guide edges 11 are formed from rigid angular metal and collectively form a receiving cavity perpendicular to the central axis. Pivot clamp 12 is provided with a torsion spring (not shown) to generate an urging force to optionally retain a cover screen member 25 within edge guides 11. In use, an operator may position (singularly or jointly with modified guide edges 11) a plurality of cover screening members 25 in guide edges 11, or may choose to operate the invention without a screening member 25 at all, depending upon operator preference.

In operation, selectable cover screen members 25 are designed to function in predetermined and preselected manners to serve an operator”s desire, i.e. to substantially block at least one of a visible wavelength entry and hence distracting audience reflection during use, to prevent a foreign object or moisture entry into shielding unit 4, and to control a wavelength amplitude exit from shielding unit 4 (sound dampening or focusing), or other use, or a user-selected combination of all. It should be understood, that an operator”s use of cover screen member 25 and the existence of guide edges 11 is optional depending upon a user”s desires and a manufacturer”s requirements. In many instances their incorporation is beneficial (see below) but it is also envisioned that uses without a cover screen and guide edges may be desirable to some end users.

In use, screen members 25 may be a debris grill (as shown), some form of conventional manual or computer controllable aperture control (not shown) with linking circuitry, an audibly transparent visual-camouflage covering (not shown) for preventing an external viewer from viewing speaker 2A or receiving unintended visible reflections therefrom, a water-proof-sound-transmitting covering (alternatively camouflage) for preventing entry of external moisture to shielding unit 4 and stage speaker device 1 while allowing sound transmission, or other form and thus enabling: (a) placement of the unit 1 in an external array of similarly shaped weather-protected lighting units, (b) expansion of available and usable weather-protected stage space (previously used to house weather-vulnerable speakers), and (c) easy operation with and incorporation into existing types of lighting arrays and computer control systems without expensive structural modifications.

Additionally referring not to FIG. 3, one embodiment of the present invention includes two bosses 20 positioned on an axis line perpendicular to the central axis on an outer diameter of rear cover 3 proximate water tight seal 7. Pivots 20a fixably join bosses 20 to rear cover 3, as shown. A yoke member 8 having two legs 8a, 8a, is pivotable about respective pivots 20a, 20a. Bosses 20, 20 are substantially circular and, at a position proximate an outer diameter of bosses 20, 20, a respective set of compression bolts 8b, 8b project opposite winged handles 21, 21.

Compression bolts 8b, 8b have projecting heads (shown) engaging the outer diameters of respective bosses 20, 20.

During use and adjustment, as winged handles are 21, 21 are tightened or loosened, and the projecting heads of bolts 20, 20 engage respective bosses 20, 20 and lock yoke member 8 relative to the pivot axis between bosses 20, 20 on rear cover 3. In this manner, bosses 20, yoke member 8 and the additional elements noted form a single axis (between bosses 20, 20) means of adjusting or positioning in stage speaker device 1.

In use, yoke member 8 is commonly fixed to an external rigid fixing structure (not shown) such as a suspended grid positioned above, behind, or in front of a stage; grids or support members positioned on either side of the stage; or behind, on the sides of, or above an audience.

In one preferred embodiment, an exterior surface 13 of stage speaker device 1 is painted a non-reflective color (for example black) selected to be similar to conventionally known stage lights and hence be visually indistinguishable and thereby visually ignored by the audience trained to ignore stage lighting fixtures through past visual experiences.

Alternatively preferred embodiments incorporate conventional single or multi-axis positioning systems to manually or electronically pan and tilt the device as required, programed or reprogrammed by an operator, or controlled by a robotic controller under computer supervision.

It is the applicants present intention to show that the inventions contained herein are adaptable for use with conventional wireless or wired audio signal control systems and may be additionally controlled in a modified multiparameter computer programmable manner enabling specialty adaptation to a stage and incorporating complex audio control, synthesizer modulation or generation, robotic manipulation, and movement control parameters into known computer control lighting systems (similar to those shown in the Sugden (Reg. No. 5,406,176) and Belliveau et all (Reg. No. 4,962,687) references above).

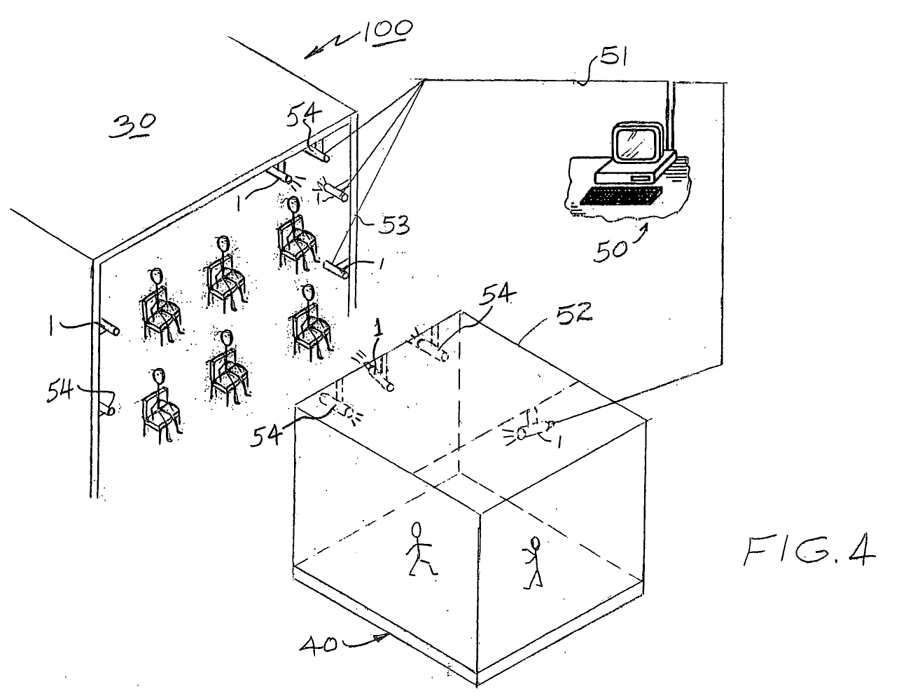

Referring now to FIG. 4, a computer controlled stage system 100 includes a plurality of stage speaker devices 1 and conventional stage lighting units 54 mounted on rigid grids 53, 52 (or other track-type lighting and sound support structures) positioned relative to a stage 40 and an audience 30. A computer controlling system 50 communicates with individual stage speaker devices 1 and stage lighting units 54 via a wired or wireless communication link 51, as shown. Communication link 51 may be readily adapted to the multiple embodiments discussed herein and will be an integral part of any sound-action and lighting-sound control, management, and generation system.

One benefit of the present invention is that units 54 and 1 are both out of the way, raised above the surface, thereby eliminating the tripping, sight-blocking hazards common in conventional stage-speaker designs and placements. In this manner those skilled in the art will understand that the present invention provides a substantial convenience benefit to users.

In operation, stage system 100 may additionally include automatic positioning systems to drive pan/tilt/rotate motions of selected ones or all of the plurality of stage speaker devices 1 and stage lighting units 54. Stage system 100, and computer controller system 50 may additionally include a transmission/reception system for transmitting wireless control signals to at least stage speaker devices 1 and for receiving confirming signals in return, or sound-action and sound-lighting timing controllers, sound generators and other electronic units as would be understood by one skilled in the art.

It should be noted that the stage speaker devices 1 as shown may be alternatively positioned to project sound towards audience 30, away from audience 30, toward actors or in other desirable directions for audio correction or compensation. Consequently, it should be understood that the positions and directions shown for stage speaker devices 1 are not limiting and may be easily adapted according to a user”s preference and need.

In at least one selected embodiment, as briefly noted above, computer controller system 50 includes conventional microprocessors, memory devices, and input devices as needed allowing an operator to provide and program detail control to an individual or the plurality of stage speaker devices 1 while simultaneously controlling stage lighting units 54.

As also noted above, In another selected embodiment, computer controller 50 is understood to be a computer control system that may optionally include links with synthesizers(s) for engineering the transmitted sound, orchestra or band recording/transmitting loops to generate a sound in addition to an electronic recorded sound generation, with lighting systems of the types mentioned above, robot movement control systems for units 1, and direct links with or integration with a theatrical light management system etc. In sum, those skilled in the art should recognize the easy adaptation of the present invention into a conventional theatrical control environment and incorporation with the previously known lighting and sound systems therein.

As one benefit of the present invention, the normally large and bulky stage speakers are deceivingly repositioned among the plurality of conventional stage lights providing an easily missed illusion to an audience trained by experience to ignore stage lighting systems normally publically positioned to dissipate thermal energy. This same analysis would apply to movie theater lighting systems normally placed well above an audience along a darkened ceiling. Since in normal use stage speakers are placed along the stage, in an immediate blocking view to the audience, and also occupy valuable stage space, there is an obviously desirable economy to enabling repositioning of the stage speakers in an assimilate-able matter to a plurality of stage lights.

As another benefit of the present invention, individual or the plurality of stage speaker devices 1 may be initially positioned and then movably repositioned (robotically or otherwise) at selected, programmed, and synchronized stop points along a computer programmed entertainment time line. This ability, enabled by the present invention, allows a stage manager/controller to easily reproduce expensive sound-movement impressions (by simply moving (pan/tilt/rotate) a speaker device 1) and to easily compensate for detrimental acoustics within a selected theatrical situation (by repositioning or repointing the speaker device 1 as needed).

In another beneficial example provided by the present invention, during a moment of soft-tone/low volume dialog in a performance, normally difficult to hear by the upper seats or in seats selectively blocked by set design/structural members etc., an operator can program movement of selected stage speaker devices to pivot and direct a channel of audible sound as desired to counteract these detriments and improve an audience”s listening experience.

In another example, an operator may direct a non-or barely-audible signal (base sound) against a reflecting and dispersing surface (i.e. a wall or ceiling) of a theater at one moment of drama (thereby extracting a maximum audience impact) and then reposition selected stage speaker devices to provide a general audible signal to the audience. The benefit of the rigid rear cover 3 filled with a medium of electro-mechanical absorption is clearly shown in this instance, since the device blocks wavelengths exiting the rear of the speaker device 1 (i.e. substantially uni-directional) and spoiling the benefit created.

Those skilled in the art should recognize that system 100 may be readily adapted to a circular or oddly shaped stage (not shown) or audience positions. Alternative track designs, the selection of additional or different configurations (for rear cover 3, body unit 2, cover 4 and other items) enable the present system 100 to be positioned in diverse areas for diverse needs while still being controlled via controller system 50.

In another example of a benefit provided by the present invention, to mimic moving sound for a biaural audience, a sound designer may custom design a pivoting movement of selected stage speaker devices from stage left to stage right, thereby replicating a surround sound or moving or fading sound effect for reduce costs. In this manner, a wide plurality of audible effect can be easily generated by a sound engineer skilled in the art of audience sound engineering with a minimum or reduced number of stage speakers.

Finally, as noted above, an alternative benefit of the present invention is to serve as a redirectable feed-back speaker for a performer. In one example, since speaker device 1 is easily moved, a performer can receive continual microphone feed-back while moving about a stage, and since the feed-back speaker is suspended as an illusory conventional stage light, the audience easily ignore the slight movement of the unit. The noted opposite to this example is where a performer wishes to have a narrow fixed feed-back speaker zone (for example, by using an elongated shielding unit 4) positioned for the performer”s specific height. In this manner, a first performer may step into their selected narrow feed-back zone during their performance, and a different second performer may step into the same position and receive feed-back from their own differently-positioned feed-back speaker selectively positioned for their second, without receiving conflicting feed-backIt should be understood by those skilled in the art that the use of the phrase cylindraceous, as used herein, is particularly drawn to objects or shapes having generally cylindrical shapes/cross-sections, but may additionally be objects being ovoidal or geometric (hex-octagon etc.) in shape/cross-section, may be a distorted or distended cylindrical, square, geometric, or ovidal shape are generally capable of having a mathematically definable radius function (but not necessarily a smoothly continuously similar radius) of any type about an type of regular or irregular circumference. Cylindraceous should and can be additionally understood herein as a triangular, rectangular, and angularized geometric cross-section having rounded corners as this shape is capable of having a mathematically definable radius function. See Webster”s Revised Unabridged Dictionary (1913 Ed.).

As noted throughout the description there are substantial utilitarian benefits from providing a stage speaker system easily used with an array or plurality of stage light. Those noted earlier and cited herein include easy of adaptation to common stage lighting structures, systems, and computer control apparatus, the reduction in costs by employing fewer speakers and the benefit of increased space (speakers not on stage), directionality, and sound quality, and audio remediation of poorly designed and therefore acoustically deficient structures, and by being able to not employ costly and conventional heavy stage speakers.

It should be further understood by those skilled in the art that the phrase “axially-aligned” should be understood as existing when individual components of the present invention are positioned generally in-line with or generally along a central axis of the overall cylindraceous shape of the stage speaker device, but there is no need to rigidly maintain a true central axis. When so aligned, the coaxial central axes of the individual rear cover, body unit, and guide or shielding unit extend (generally aligned) to form the long self-defined “central axis” of the resultant cylindraceous stage speaker device. See Webster”s Revised Unabridged Dictionary (1913 Ed.). It should be understood, that in an alternative embodiment, where a light (not shown) is combined with speaker 2A within the same body housing 2, that the general coaxial nature of the unit is maintained despite any axial displacement of the speaker. In this way, the present invention envisions close combination with adaptive lighting techniques within the same mechanical housing.

It should be additionally understood by those skilled in the art that, where used, the phrase a medium of electro-mechanical energy absorption, may be any medium, or combination of mediums, capable of at least minutely reducing an energy state of a traveling electromechanical or sound wave. Specifically, it is to be understood that such a medium includes atmospheric air (non-vacuum state), a particular selected gas or combination of gases (for density change energy absorption), a foam containing any gas or mixtures of gasses, and/or a mechanical energy absorbing means (such as mechanical baffles) all positioned within a substantially bounded space.

Another alternative embodiment envisioned positions the at least one speaker proximate the front opening or the rear portion of the speaker unit. Where a speaker is positioned proximate the front opening the entire speaker unit may be shortened along it”s central axis providing a more convenient shape. Where a speaker is positioned proximate the rear portion of the speaker unit a similar shortening-benefit may result. In this manner, the present invention envisions an easy adaptation to a variety of manufacturer, set-design, and sound-architectural needs.

It will be recognized by those skilled in the art that the present invention encompasses an alternative design enabling the transmission of high-frequency (tweeter) range sound waves from the face of a speaker to the front opening of the speaker without interference with the longer wave length mid-or-base range sound waves. Such a design may include the use of a bounded sound directing channel member passing from a front face of the speaker to the front opening. While no particular design is required, the present invention envisions a horn-like bounded directional channel having a small end proximate the speaker face and a wider/larger end proximate the front opening of the unit.

In the claims, meansor stepclauses are intended to cover the structures described or suggested herein as performing the recited function and not only structural equivalents but also equivalent structures. Thus, for example, although a nail, a screw, and a bolt may not be structural equivalents in that a nail relies on friction between a wooden part and a cylindrical surface, a screw's helical surface positively engages the wooden part, and a bolt”s head and nut compress opposite sides of a wooden part, in the environment of fastening wooden parts, a nail, a screw, and a bolt may be readily understood by those skilled in the art as equivalent structures.

Having described at least one of the preferred embodiments of the present invention with reference to the accompanying drawings, it is to be understood that the invention is not limited to those precise embodiments, and that various changes, modifications, and adaptations may be effected therein by one skilled in the art without departing from the scope or spirit of the invention as defined in the appended claims. Accordingly, all such modifications are intended to be included within the spirit and scope of this invention as defined in the following claims.

1. A cylindraceous stage speaker system, comprising:
a cylindraceous body unit defining a first axis;
said body unit including at least one speaker having at least a front speaker face and a rear speaker face;
said front speaker face positioned at a first side of said body unit opposite an open second side;
at least a cylindraceous rear cover unit coaxial to said first axis, defining a single cylindraceous opening, and continuously bounding a respective enclosed space defined therein in which a medium of electro-mechanical energy absorption is disposed;
means for securing said body unit to said rear cover unit; and
a total length of said cylindraceous stage speaker system being defined along said first axis and being the same as or greater than a maximum diameter of said stage speaker system along said axis.

2. A cylindraceous stage speaker system, according to claim 1, wherein:
a ratio x of said total length to said maximum diameter is defined as substantially about 1.0s<<=×<<=3.5,
whereby said stage speaker system is shaped for easy positioning and repositioning during a use by a user.

3. A cylindraceous stage speaker system, according to claim 1, further comprising:
clamping means for removably clamping said body unit to said rear cover unit; and
said means for clamping forming at least one of a substantially sound-tight and a substantially water-tight seal.

4. A cylindraceous speaker system, according to claim 1, further comprising:
means for controllably positioning said speaker system relative to at least one external fixture plane;
said means for controllably positioning including at least two opposing bosses on said body unit defining a line perpendicular to said first axis;
a first set of engaging elements threadably engageable with respective said bosses;
at least one yoke member; and
ones of said set of engaging elements adjustably connecting respective ends of said yoke member to said opposing bosses, whereby said means for controllably positioning allows a user to repositionably position said speaker system relative to said at external fixture plane.

5. A cylindraceous speaker system, according to claim 4, further comprising::
means for securing said rear cover to said main body unit;
said means for securing in said means for removably clamping; and
said means for securing including at least one of a braided metal cable release-ably joining said rear cover to said main body unit, whereby when said means for removable clamping releases said main body unit said means for securing prevents unintended separation of said rear cover.

6. A cylindraceous speaker system, according to claim 1, further comprising:
a shielding unit extending coaxial to said first axis of said body unit;
at least one cover screening member; and
means for removably securing said one cover screening member to said shielding unit; whereby said at least one cover screening member substantially covers a front opening of said shielding unit during said use and controls at least one of a visible wavelength entry and reflection, a foreign object entry into said shielding unit, and an energy wavelength exit from said shielding unit.

7. A cylindraceous speaker system, according to claim 6, wherein:
said at least one screening member includes at least one of a debris grill, an aperture control means for controlling an aperture of said fourth cylindrical opening, a sound transmitting camouflage covering means for preventing an external viewer from viewing said speaker means, and a waterproof-sound-transmitting means for preventing entry of an external moisture to said fourth cylindrical opening during an outdoor use.

8. A cylindraceous speaker system, according to claim 2, further comprising:
a shielding unit extending coaxial to said first axis of said body unit;
at least one cover screening member; and
means for removably securing said one cover screening member to said shielding unit; whereby said at least one cover screening member substantially covers a front opening of said shielding unit during said use and controls at least one of a visible wavelength entry and reflection, a foreign object entry into said shielding unit, and an energy wavelength exit from said shielding unit.

9. A cylindraceous speaker system, according to claim 8, wherein:
said at least one screening member includes at least one of a debris grill, an aperture control means for controlling an aperture of said front opening, a sound transmitting camouflage covering means for preventing an external viewer from viewing said speaker means, and a waterproof-sound-transmitting means for preventing entry of an external moisture to said fourth cylindrical opening during an outdoor use.

10. A cylindraceous speaker system, according to claim 1, further comprising:
waterproof means in said rear cover opposite said first cylindrical opening for guiding a wired audio connection from a rear face of said rear cover to said speaker means.

11. A cylindraceous speaker system, according to claim 1, further comprising:
a plurality of rigid heat-radiating fins;
said plurality of fins arrayed about an outer diameter of said rear cover opposite said speaker means; and
each said fin radiating a thermal energy of said speaker system to a surrounding atmospheric system, whereby said speaker system prevents an undesirable buildup of thermal energy during said use.

12. A cylindraceous stage speaker system, comprising:
a central body unit having a first axis;
said body unit including on an inner diameter, a coaxially positioned speaker means having at least a front speaker face and a rear speaker face;
said front speaker face positioned at a first side of said body unit opposite an open second side of said body unit;
a cylindraceous rear cover unit having a rigid housing; said rear cover bounding a respective space defined therein in which a medium of electro-mechanical energy absorption is disposed;
said rear cover being coaxial to and defining an opening coaxial to said first axis;
clamping means for removably clamping said central body unit to said rear cover and for forming at least one of a substantially water-tight, a substantially sound-tight seal, and quick-release connection between said speaker unit and said rear cover;
a shielding unit bounding a first and a second cylindraceous opening;
said first and second openings being coaxial to each first axis;
said shielding unit substantially coaxial to each of said first axis, said body unit, said rear cover, and said speaker means,
a total length of said cylindraceous stage speaker system being defined along said first axis;
a maximum diameter of said stage speaker being a maximum diameter of said rear cover unit; and
a ratio x of said total length to said maximum diameter is defined as substantially about 1.0×3.53.5 by said stage speaker system is shaped for easy positioning and repositioning during a use by a user.

13. A cylindraceous speaker system, according to claim 12, further comprising:
means for controllably positioning said speaker system relative to at least one external fixture plane;
said means for controllably positioning including at least two opposing bosses on said body unit defining a line perpendicular to said first axis;
a first set of compression elements threadably engageable with respective said bosses;
at least one yoke member; and
ones of said set of compression member adjustably connecting respective ends of said yoke member to said opposing bosses, whereby said means for controllably positioning allows a user to repositionably position said speaker system relative to said at external fixture plane.

14. A cylindraceous speaker system, according to claim 13, further comprising:
means for securing said rear cover to said main body unit;
said means for securing in said means for removably clamping; and
said means for securing including at least one of a braided metal cable release-ably joining said rear cover to said main body unit, whereby when said means for removable clamping releases said main body unit said means for securing prevents unintended separation of said rear cover.

15. A cylindraceous speaker system, according to claim 13, further comprising:
at least one cover screening member; and
means for removably securing said one cover screening member to said fourth cylindrical opening of said shielding unit; whereby said at least one cover screening member substantially covers said fourth cylindrical opening during said use and controls at least one of a visible wavelength entry and reflection, a foreign object entry into said shielding unit, and an energy wavelength exit from said shielding unit.

16. A cylindraceous speaker system, according to claim 15, wherein:
said at least one screening member includes at least one of debris grill, an aperture control means for controlling an aperture of said fourth cylindrical opening, a sound transmitting camouflage covering means for preventing an external viewer from viewing said speaker means, and a waterproof-sound-transmitting means for preventing entry of an external moisture to said fourth cylindrical opening during an outdoor use.

17. A cylindraceous speaker system, according to claim 14, further comprising:
at least one cover screening member; and
means for removably securing said one cover screening member to said fourth cylindrical opening of said shielding unit; whereby said at least one cover screening member substantially covers said fourth cylindrical opening during said use and controls at least one of a visible wavelength entry and reflection, a foreign object entry into said shielding unit, and an energy wavelength exit from said shielding unit.

18. A cylindraceous speaker system, according to claim 17, wherein:
said at least one screening member includes at least one of debris grill, an aperture control means for controlling an aperture of said fourth cylindrical opening, a sound transmitting camouflage covering means for preventing an external viewer from viewing said speaker means, and a waterproof-sound-transmitting means for preventing entry of an external moisture to said fourth cylindrical opening during an outdoor use.

19. A cylindraceous speaker system, according to claim 12, further comprising:
waterproof means in said rear cover opposite said first cylindrical opening for guiding a wired audio connection from a rear face of said rear cover to said speaker means.

20. A cylindraceous speaker system, according to claim 12, further comprising:
a plurality of rigid heat-radiating fins;
said plurality of fins arrayed about an outer diameter of said rear cover opposite said speaker means; and
each said fin radiating a thermal energy of said speaker system to a surrounding atmospheric system, whereby said speaker system prevents an undesirable buildup of thermal energy during said use.

21. A computer controlled stage speaker system, comprising:
at least one stage speaker system;
at least one multiparameter lighting unit system;
computer control means for computerized controlling of said at least one stage speaker system and said multiparameter lighting unit system; and
said computer control means enabling a communication means for directing said at least one stage speaker system to position-ably reposition based upon a series of stored and programmable movement commands and for initiating at least one of a sound generation, a sound synthesis, and a sound reproduction of at least one of a digitally and an analog signal, according to a programable and updatable computer controlled sequence stored in said computer control means during a use.

22. A computer controlled stage speaker system, according to claim 21, wherein:
said at least one stage speaker system comprises:
a body unit having a first axis;
said body unit including a coaxially positioned speaker having at least a front speaker face and a rear speaker face;
said front speaker face positioned at a first side of said body unit opposite an open second side;
a rear cover unit coaxial to said first axis, continuously bounding a respective enclosed space defined therein in which a medium of electro-mechanical energy absorption is disposed;
said rear cover unit on said body unit forming at least one of a substantially water-tight and a substantially sound-tight seal; and
a total length of said cylindraceous stage speaker system being defined along said first axis and being the same as or greater than a maximum diameter of said stage speaker system.

23. A computer control stage speaker system, according to claim 22, wherein:
said programmable and undatable computer controlled sequence includes data applicable to at least one of a sound, a position, and an volume parameter set stored in a memory of said computer control system.

24. A computer controlled stage speaker system, according to claim 23, wherein:
said communication means includes at least one of a wired and a wireless communication network communicating between said computer control system and said at least one stage speaker system and said lighting unit.

25. A computer controlled stage speaker system, according to claim 24, wherein:
said at least one communication network communicates at least one of a digital and an analog signal to said at least one speaker system including at least one of an audible and an inaudible signal.

26. A method of mounting at least one stage speaker system, comprising the steps of:
selecting at least one stage speaker system including at least a first external surface on at least one of a body unit, a rear cover unit, and a shielding unit; and
at least one of a heat sink element, a heat radiation coating, and a heat radiation element on said at least first external surface, whereby said at least one element enables desirable placement of said stage speaker system proximate a plurality of stage lighting units minimizing purchase costs and operator training;
said stage speaker system being repositionably fix-able to a stage lighting assembly structure and including at least a first means for adjustably fixing said stage lighting assembly structure relative to a desired target;
positionably determining said at least one stage speaker system on said stage lighting assembly structure proximate said plurality of stage lighting units; and
operably connecting said stage speaker system to a computer control system for controlling a positioning and at least one of an audible and inaudible operation of said stage speaker system while simultaneously controlling an operation of said plurality of stage lights,
whereby said step of operably connecting includes a step of synchronized controlling of both said plurality of stage lights and said stage speaker system during a performance while permitting a generation of sound toward said desired target.

27. A cylindraceous stage speaker system, comprising:
a body unit having a first axis;
said body unit including a speaker having at least a front speaker face and a rear speaker face;
said front speaker face positioned at a first side of said body unit opposite an open second side;
a rear cover unit coaxial to said first axis, defining at least a first opening and continuously bounding a respective enclosed space defined therein in which a medium of electro-mechanical energy absorption is disposed;
clamping means for removably clamping said body unit to said rear cover unit and for forming at least one of a water-tight and a sound-tight seal therewith proximate said first opening; and
means for controllably positioning said speaker system relative to at least one external fixture plane;

28. A cylindraceous stage speaker system, comprising: a body unit having a first axis;
said body unit including proximate an inner diameter a fixably positioned speaker means having at least a front speaker face and a rear speaker face;
said front speaker face positioned at a first side of said body unit opposite an open second side of said body unit;
said open second side of said body unit being a first cylindrical opening surrounding said rear speaker face;
a rear cover unit having a rigid housing;
said rear cover continuously bounding a respective space defined therein in which a medium of electro-mechanical energy absorption is at least partially restrained;
said rear cover being substantially coaxial to and defining a single second cylindrical opening;
said second cylindrical opening coaxial to said first cylindrical opening;
a shielding unit bounding a third cylindrical opening and a fourth cylindrical opening;
said third and fourth cylindrical openings being coaxial to each said first and second cylindrical opening;
said third cylindrical opening being removably joined to said body unit forming at least one of a water-resistant and a sound-resistant joining there between; and
said shielding unit coaxial to each of said first axis and said body unit, said rear cover, and said speaker means.

29. The combination of a cylindraceous stage speaker unit and a multi-parameter stage lighting unit, the combination comprising:
at least a first cylindraceous multi-parameter stage lighting unit;
at least a first cylindraceous stage speaker unit; said stage lighting unit including at least a first housing having at least a first open end for the projection of an illumination wavelength toward a first selected target;
first means for adjustably fixing said first cylindraceous housing to an external lighting unit support structure and enabling an adjustment of said first open end relative to said first selected target during a use;
said stage speaker system including at least a second housing substantially similar to said at least first housing and having at least a second open end opposite a third closed end;
said second open end enabling the projection of an audible wavelength toward a second selected target;
second means for adjustably fixing said second housing to said external light unit support structure and enabling an adjustment of said second open end relative to said second selected target during said use; and
said second means for adjustably fixing being substantially similar to said first means for adjustably fixing, whereby said stage lighting unit and said stage speaker system are substantially and include substantially similar outward appearances.

30. The combination, according to claim 29, further comprising:
a second end covering device covering said second open end of said stage speaker system and substantially preventing at least one of an entry and an emission of visible wavelengths of light there-through while remaining substantially transparent to the transmission of audible wavelengths, and
said third end of said stage speaker unit being both optically opaque and audibly opaque.

31. The combination, according to claim 30, wherein:
said second end covering is at least one of a grill unit and an optically reflective member.

32. The combination, according to claim 31, wherein:
said grill unit includes a plurality of openings sufficiently sized to diffuse the entry of and limit the reflection and exit of visible wavelengths from an interior of said second cylindraceous housing during said use, whereby an audience is not able to view an interior of said stage speaker unit with reflected light.

33. A stage speaker system, comprising:
a cylindraceous body unit defining an first axis;
said body unit including at least one speaker having at least a front speaker face and a rear speaker face;
a rear cover unit on said body unit;
a shielding unit on said body unit opposite said rear cover unit and defining at least a first audio pathway away from said front speaker face;
at least a first external surface on at least one of said body unit, said rear cover unit, and said shielding unit; and
at least one of a heat sink element, a heat radiation coating, and a heat radiation element on said at least first external surface, whereby said at least one on said at least first external surface enables a placement of said stage speaker system proximate an array of external stage lighting units.

34. A stage speaker system, comprising:
a cylindraceous body unit defining an first axis;
said body unit including at least one speaker having at least a front speaker face and a rear speaker face;
a rear cover unit on said body unit;
a shielding unit on said body unit opposite said rear cover unit and defining at least a first audio pathway away from said front speaker face;
at least a first external surface on at least one of said body unit, said rear cover unit, and said shielding unit; and
at least one of a heat sink element, a heat radiation coating, and a heat radiation element on said at least first external surface, whereby said at least one on said at least first external surface enables said system to present no outward appearance of a speaker.

35. A stage speaker system, comprising:
a cylindraceous body unit defining an first axis;
said body unit including at least one speaker having at least a front speaker face and a rear speaker face;
at least a rear cover unit on said body unit;
at least a first external surface on at least one of said body unit, said rear cover unit, and said shielding unit; and
at least one of a heat sink element, a heat radiation coating, and a heat radiation element on said at least first external surface, whereby said speaker is internally mounted within said stage speaker system and not externally visible to an external audience.
